(19) United States
(12) Patent Application Publication
(10) Pub. No.: US 2009/0075044 A1
(43) Pub. Date: Mar. 19, 2009

(54) SUBSTRATE HAVING CONDUCTIVE LAYERS, DISPLAY DEVICE, AND METHOD FOR MANUFACTURING SUBSTRATE HAVING CONDUCTIVE LAYERS

(75) Inventor: Toshihide Tsubata, Mie (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: Sharp Kabushiki Kaisha, Osaka-shi, Osaka (JP)

(21) Appl. No.: 11/910,791

(22) PCT Filed: Mar. 30, 2006
(86) PCT No.: PCT/JP2006/306751

§ 371 Date: Oct. 5, 2007

(30) Foreign Application Priority Data
Apr. 6, 2005 (JP) 2005-110375

(51) Int. Cl. B32B 7/02; H01L 21/00

(52) U.S. Cl. 428/213; 430/311

(57) ABSTRACT

A substrate has a conductive layer containing abundantly obtainable zinc oxide that is hardly eroded. The substrate has a laminate structure in which a plurality of conductive layers including at least a first conductive layer containing zinc oxide as a main component are laminated, and a second conductive layer provided in the laminate structure so as to be positioned in a surface in contact with a substance used in a chemical treatment carried out to form the conductive layers is made of material which is less likely to be eroded by the substance than the zinc oxide.

### BACKGROUND OF THE INVENTION

1. Field of the Invention

The present invention relates to (i) a substrate, having conductive layers, which is usable as a display substrate such as an active matrix substrate and a color filter substrate, (ii) a display device, and (iii) a method for manufacturing a substrate having conductive layers.

2. Description of the Related Art

Currently, a liquid crystal display device is characterized by its small size, thinness, low power consumption, and lightness. Due to these characteristics, the liquid crystal display device is widely used in various kinds of electronic devices. Particularly, an active matrix liquid crystal display device having a switching element as an active element allows for display properties equal to those of CRT (Cathode Ray Tube), so that such a liquid crystal display device is widely used for OA devices such as a personal computer, AV devices such as a television, and mobile phones. Recently, the liquid crystal display device has greatly improved in quality such as a larger size, higher definition, a larger pixel-available area (higher aperture), and the like. Typically, a liquid crystal panel of the liquid crystal display device is manufactured as follows. An active matrix substrate and a color filter substrate are combined with each other so that the color filter is opposite to the active matrix substrate, and liquid crystal is injected into a gap between these substrates. Further, drivers and the like are connected to leading-out terminals of the liquid crystal panel, thereby manufacturing the liquid crystal display device.

In the active matrix substrate serving as a component of the liquid crystal display device for achieving the foregoing object, signal lines and scanning lines are provided on an insulative substrate, and a switching element and a pixel electrode are provided on a junction of each signal line and each scanning line.

Further, as described above, the color filter substrate is combined with the active matrix substrate so that these substrates are opposite to each other and liquid crystal is injected into a gap between both the substrates, thereby manufacturing the liquid crystal display device. Herein, an example of the color filter substrate is a substrate formed so that its color regions R(red), G(green), and B(blue) respectively correspond to pixel regions of the active matrix substrate, and a black matrix (light shielding film) is formed so as to cover portions other than the respective pixel regions, and transparent electrodes are formed thereon.

Furthermore, particularly a liquid crystal display device used in a large-size television has been recently desired to have a higher response speed and an improved viewing angle property (technique for increasing a viewing angle) as its performances. Further, a multi-domain vertical alignment (MVA) liquid crystal display device adopting techniques for satisfying these requirements has been proposed (see, for example, Japanese Unexamined Patent Publication No. 242225/1999 (Tokukaihei 11-242225)).

In order to realize the foregoing performances, an active matrix substrate or a color filter substrate of the MVA type liquid crystal display device is equipped with a protrusion (protrusion for controlling alignment) or an electrode slit which controls pre-tilt of liquid crystal molecules.

FIG. 9 is a plan view illustrating a pixel of an active matrix substrate 130 of the MVA type display device and a part of a pixel adjacent to that pixel. Note that, the active matrix substrate 130 illustrated in FIG. 9 includes a thin film transistor array. As illustrated in FIG. 9, a gate line (scanning line) 101 and a source line (signal line) 102 are disposed so as to intersect each other in the pixel of the active matrix substrate 130. At a junction of the gate line 101 and the source line 102, a switching element (thin film transistor: hereinafter, referred to as “TFT”) 114 and a pixel electrode 103 are disposed. The switching element 114 includes: a gate electrode 104 connected to the gate line 101; a source electrode 105 connected to the source line 102; a drain electrode 106a connected to the pixel electrode 103; and an island-shaped semiconductor layer 125.

A drain leading electrode 106b is connected to the pixel electrode 103 via a contact hole 109. Further, the drain leading electrode 106b is provided opposite to an auxiliary capacitor line 107 with a gate insulating film 111 therebetween so as to provide an auxiliary capacitor.

Next, the following briefly describes a method for forming the thin film transistor array, taking the active matrix substrate 130 as an example, with reference to FIG. 9 and FIG. 10. Note that, FIG. 10 is a cross sectional view taken along a D1-D2 line of the thin film transistor array illustrated in FIG. 9.

First, the gate line (scanning line) 101, the gate electrode 104, and the auxiliary capacitor line 107 are simultaneously formed on a substrate 110 made of transparent insulative material such as glass by means of film formation, photolithography, and etching.

Next, a gate insulating film 111, an active semiconductor layer 112, and a low-resistance semiconductor layer (e.g., n-type amorphous silicon) 113 are formed so as to form an island-shaped semiconductor layer 125 by means of photolithography and etching.

Further, a source line 102, a source electrode 105, a drain electrode 106a, and a drain leading electrode 106a are simultaneously formed by means of film formation, photolithography, and etching, and the n-type semiconductor layer 113 is subsequently etched so as to be divided into a source and a drain.

Thereafter, a lower interlayer insulating film 120 made of SiNx (silicon nitride film) is formed so as to cover the entire surface. Subsequently, an upper interlayer insulating film 115 made of photosensitive acryl resin is formed, and then a contact hole pattern is formed, by means of photolithography, at a position where the contact hole 109 is to be formed.

Next, the lower interlayer insulating film 120 and the gate insulating film 111 are sequentially etched so as to form the contact hole 109, a gate line leading-out terminal, and a source line leading-out terminal.

Further, a transparent conductive film made of ITO (indium tin oxide) is formed so as to coat the contact hole 109, the gate line leading-out terminal, and the source line leading-out terminal, and the pixel electrode 103, a gate line leading-out terminal top layer electrode, and a source line leading-out terminal top layer electrode are formed by means of photolithography and etching.

Note that, in order to control alignment of liquid crystal molecules, a slit pattern 150 is provided on the pixel electrode. Further, the contact hole 109 allows the drain electrode 106a of the TFT and the pixel electrode 103 to be connected to each other via the drain leading electrode 106b.

In accordance with the foregoing method, the source line 102 and the pixel electrode 103 can be separated from each other with the interlayer insulating films 115 and 120 therebetween in the active matrix substrate 130.

By adopting the method in which the source line 102 and the pixel electrode 103 are separated from each other, it is possible to prevent decrease in the yield which is caused by short-circuit of the pixel electrode 103 and the source line 102. Further, as illustrated in FIG. 9, the pixel electrode 103 and the source line 102 can be made to overlap each other seen from the above, so that it is possible to improve the aperture of the liquid crystal display device.

Next, the following describes the color filter substrate 210 of the MVA type display device with reference to FIG. 11 and FIG. 12. FIG. 11 is a plan view illustrating a pixel of the color filter substrate 210 of the MVA type display device and a part of a pixel adjacent to that pixel. FIG. 12 is a cross sectional view taken along an E1-E2 cross sectional line of FIG. 11 so as to illustrate the color filter substrate.

The color filter substrate 210 is typically arranged so as to include: a color filter layer 222 constituted of a three-primary-color (red, green, and blue) layer 220, a black matrix layer (hereinafter, referred to as “BM”) 221, and the like; a counter electrode 223 made of ITO; an alignment film (not shown); and a protrusion 224 for controlling alignment, wherein these members are formed on a transparent substrate 200.

On the transparent substrate 200, a negative acrylic photosensitive resin liquid or the like in which carbon fine particles have been dispersed is applied by spin coating, and then the resultant is dried, so as to form a black photosensitive resin layer. Subsequently, the black photosensitive resin layer is exposed via a photo mask, and then the resultant is developed, so as to form the BM 221. At this time, on a region where a first coloring layer (e.g., a red layer) is to be formed, a first coloring layer opening is formed. On a region where a second coloring layer (e.g., a green layer) is to be formed, a second coloring layer opening is formed. On a region where a third coloring layer (e.g., a blue layer) is to be formed, a third coloring layer opening is formed. Note that, the openings are formed so as to respectively correspond to the pixel electrodes of the active matrix substrate.

Next, a negative acrylic photosensitive resin liquid in which dye has been dispersed is applied by spin coating, and then the resultant is dried, and exposure and development are carried out by using a photo mask, so as to form a red layer positioned in the first coloring layer opening.

Thereafter, the same operation is carried out with respect to the second coloring layer (e.g., green layer) and the third coloring layer (e.g., blue layer), thereby completing formation of the color filter layer 222. Further, the transparent electrode 223 made of ITO is formed by means of sputtering. Thereafter, a positive phenol novolak photosensitive resin liquid is applied by spin coating, and then the resultant is dried, and exposure and development are carried out by using a photo mask, so as to form a vertical alignment controlling protrusion 224. In this manner, the color filter substrate is formed.

Note that, as in the pixel electrode 103 of the active matrix substrate 130, a slit pattern for controlling alignment of liquid crystal molecules may be provided instead of the vertical alignment controlling protrusion 224 provided on the color filter substrate 210 of the MVA type. An alignment controlling protrusion arranged in the same manner as in the protrusion provided on the color filter substrate 210 may be provided instead of forming the slit pattern 150 on the pixel electrode 103 of the active matrix substrate 130.

Incidentally, the aforementioned color filter substrate or active matrix substrate essentially includes the transparent conductive film, and the transparent conductive film is produced by using electrode material such as ITO (indium oxide containing tin), IZO (indium oxide containing zinc), and the like. However, the transparent conductive film is expensive since it contains indium which is a rare metal, and this is likely to result in short supply. Thus, a problem occurs in production of the color filter substrate and production of the active matrix substrate. On the other hand, it is advantageous to use zinc oxide (hereinafter, referred to as “ZnO”) since there are bountiful amounts of zinc oxide as natural resources. For example, Japanese Unexamined Patent Publication No. 124530/1987 (Tokukaisho 62-124530) describes that ZnO is used to form a transparent electrode.

However, in the case of using ZnO in forming a transparent electrode film in arrangements of the active matrix substrate and the color filter substrate and in the manufacturing method thereof, this raises a problem in anti-corrosion property (anti-erosion property).

Specifically, in the case of using ZnO in forming the pixel electrode, the gate line leading-out terminal top electrode, and the source line leading-out terminal top electrode of the active matrix substrate, this raises the following problem. That is, a photosensitive resist such as phenol novolak resin is applied, exposed, and developed by using a photolithography technique, so as to form pattern shapes of the pixel electrode, the gate line leading-out terminal top layer electrode, and the source line external drawing top layer electrode, and the resultant shapes are etched by using a resist pattern as a mask, and then the resist pattern is peeled off with a peeling agent so as to be removed therefrom, but there is such a problem that ZnO is eroded in the peeling step.

Further, in the case of using ZnO in forming the pixel electrode, the gate line leading-out terminal top layer electrode, and the source line external drawing top layer electrode of the active matrix substrate, this raises the following problem. That is, in the case where a positive photosensitive resist such as phenol novolak resin is applied, exposed, and developed by using a photolithography technique, so as to form pattern shapes of the pixel electrode, the gate line leading-out terminal top layer electrode, and the source line external drawing top layer electrode, and the resultant shapes are etched by using a resist pattern as a mask, there is such a problem that ZnO is eroded on the occasion of problems in the application/exposure of the resist in the lithography step.

Further, on the occasion of problems in the application/exposure/development of the resist, it is necessary to peel the resist film with a resist peeling agent and to carry out photolithography again (photo rework). There is such a problem that the peeling agent erodes ZnO at the time of the photo rework.

The aforementioned problems can arise not only in the substrate of the aforementioned MVA type liquid crystal display device but also in a substrate, having a transparent electrode conductive layer subjected to the lithography step, which is provided on a liquid crystal display device other than the MVA type, e.g., various display devices such as an EL (electro luminescence) display device and a plasma display device, a photoelectric transfer device such as a solar battery, and a touch panel.

Further, in the aforementioned MVA type liquid crystal display device, when forming the vertical alignment controlling protrusion instead of forming the slit for controlling liquid crystal molecules on the pixel electrode of the active matrix substrate, a positive photosensitive resist such as phenol novolak resin is applied to the pixel electrode, and exposure and development are carried out so as to form a pattern. However, there is such a problem that ZnO in an unexposed region is eroded by a developer in forming the vertical alignment controlling protrusion.

Further, in the MVA type liquid crystal display device, also when using ZnO in forming the transparent electrode of the color filter substrate, the same problem as in the aforementioned active matrix substrate occurs. That is, the pattern of the vertical alignment controlling protrusion is formed by applying, exposing, and developing a positive photosensitive resist such as a phenol novolak resin, for example, but there is such a problem that ZnO existing on a region other than the vertical alignment controlling protrusion is eroded by the developer in forming the protrusion. Further, when forming the vertical alignment controlling protrusion, there is such a problem that ZnO existing on a region in which the photosensitive resin pattern is fractured due to troubles in application and exposure of the photosensitive resist is eroded by the developer after the exposure. Further, there is such a problem that ZnO is eroded by the peeling agent at the time of photo-rework. Further, when forming the slit instead of the vertical alignment controlling protrusion, there is such a problem that ZnO is eroded by the developer in the photolithography step or is eroded by the peeling agent at the time of photo-rework.

### SUMMARY OF THE INVENTION

In order to overcome the problems described above, preferred embodiments of the present invention provide (i) a substrate whose conductive layer containing abundantly obtainable zinc oxide is hardly eroded, and (ii) a display device including such a substrate.

In accordance with a preferred embodiment of the present invention, a substrate includes a laminate structure in which a plurality of conductive layers including at least a first conductive layer containing zinc oxide as a main component are laminated, wherein a second conductive layer provided in the laminate structure so as to be positioned in a surface in contact with a substance used in a chemical treatment carried out to form the conductive layers is made of a material which is less likely to be eroded by the substance than the zinc oxide.

According to this preferred embodiment of the present invention, even though the first conductive layer containing economically accessible zinc oxide as a main component is preferably used, it is possible to prevent the first conductive layer from being eroded by the chemical treatment carried out to form the conductive layers. That is, the second conductive layer which is in contact with the substance used in the chemical treatment is less likely to be eroded by the substance than zinc oxide, and the first conductive layer is not in contact with the substance, so that the first conductive layer is hardly eroded. Thus, the present invention is effective in being applied to (i) a substrate in which a photosensitive resist is applied and conductive layers are etched by using a patterned photosensitive resist as a mask, and (ii) a substrate in which a photosensitive resist is formed on a conductive layer through patterning.

In order to solve the foregoing problems, a substrate according to a preferred embodiment of the present invention includes a laminate structure in which a plurality of conductive layers including at least a first conductive layer containing zinc oxide as a main component are laminated, wherein a second conductive layer positioned in a surface in contact with a photosensitive resist in a photolithography step is made of material which is less likely to be eroded by a developer for developing the photosensitive resist than the zinc oxide.

According to the above-described preferred embodiment of the present invention, even though the first conductive layer containing economically accessible zinc oxide as a main component is preferably used, the first conductive is hardly eroded by the developer in developing the photosensitive resist formed on the side of the second conductive layer of the laminate structure. Thus, the present invention is effective in being applied to (i) a substrate in which conductive layers are etched by using a patterned photosensitive resist as a mask, and (ii) a substrate in which a photosensitive resist is formed on a conductive layer through patterning. Further, a layer containing zinc oxide as a main component in a region where the resist pattern is fractured by erroneous application and exposure of the resist at the time of photolithography is hardly eroded by the developer after the exposure. Further, in a substrate used in an MVA type liquid crystal display device, the second conductive layer exists in forming a vertical alignment controlling protrusion with the photosensitive resist, so that it is possible to suppress the layer whose main component is zinc oxide from being eroded by the developer.

Further, a substrate according to a preferred embodiment of the present invention includes a laminate structure in which a plurality of conductive layers including at least a first conductive layer containing zinc oxide as a main component are laminated, wherein a second conductive layer positioned in a surface in contact with a photosensitive resist in a photolithography step is made of material which is less likely to be eroded by a peeling agent for peeling the photosensitive resist than the zinc oxide.

According to the above-described preferred embodiment of the present invention, even though the first conductive layer containing economically accessible zinc oxide as a main component is preferably used, it is possible to suppress the layer whose main component is zinc oxide from being eroded by the peeling agent in a step of peeling the resist pattern with the peeling agent.

Further, the substrate according to a preferred embodiment of the present invention is arranged so that the second conductive layer is made of ITO or IZO.

According to the arrangement, it is possible to adopt a conventional manufacturing process which is similar to a manufacturing process carried out in the case where the conductive layer is made only of ITO or IZO, so that it is not necessary to newly develop a manufacturing process in treating portions to which the conventional manufacturing process is applicable. Further, formation of the first conductive layer whose main component is zinc oxide allows adjustment of an amount of ITO constituting the second conductive layer.

Further, the substrate according to a preferred embodiment of the present invention is arranged so that the first conductive layer is thicker than the second conductive layer.

According to the arrangement, a lesser amount of indium which is a rare metal is required, so that it is possible to realize stable production and supply without being influenced by a quantity of supplied indium.

The substrate according to a preferred embodiment of the present invention is arranged so that each of the conductive layers serves as a pixel electrode so as to constitute an active matrix substrate.

According to the above-mentioned preferred embodiment of the present invention, even though the layer containing economically accessible zinc oxide as a main component is preferably used to form the pixel electrode, it is possible to suppress the layer whose main component is zinc oxide from being eroded by at least either the developer for developing the photosensitive resist used in the photolithography step or the peeling agent for peeling the photosensitive resist used in the photolithography step. As a result, it is possible to realize favorable display quality and it is possible to improve the yield.

The substrate according to a preferred embodiment of the present invention is arranged so that each of the conductive layers serves as a transparent electrode so as to constitute a color filter substrate.

According to the above-mentioned preferred embodiment of the present invention, even though the layer containing economically accessible zinc oxide as a main component is preferably used to form the transparent electrode, it is possible to suppress the layer whose main component is zinc oxide from being eroded by at least either the developer for developing the photosensitive resist used in the photolithography step or the peeling agent for peeling the photosensitive resist used in the photolithography step. As a result, it is possible to realize favorable display quality and it is possible to improve the yield.

The substrate according to a preferred embodiment of the present invention is arranged so that the second conductive layer of the laminate structure has an alignment controlling protrusion.

According to the above-described preferred embodiment of the present invention, even though the alignment controlling protrusion is formed by patterning with the photosensitive resist on the substrate used in the MVA type liquid crystal display device, the second conductive layer exists, so that the layer whose main component is zinc oxide is hardly eroded by the developer. Further, the second conductive layer exists also at the time of photo rework, so that the layer whose main component is zinc oxide is hardly eroded by the peeling agent. As a result, it is possible to realize favorable display quality and it is possible to improve the yield.

The substrate according to a preferred embodiment of the present invention is arranged so that each of the conductive layers has a slit.

According to the arrangement, it is possible to obtain a substrate for a wide viewing angle display device which substrate is used in the MVA type liquid crystal display device.

A display device according to yet another preferred embodiment of the present invention includes a substrate according to any one of the aforementioned preferred embodiments of the present invention.

According to this arrangement, since the substrate according to the above-described preferred embodiments of the present invention is used for a display device, it is possible to adopt a conventional manufacturing process. As a result, stable production can be realized at low cost, so that it is possible to provide a display device having a high aperture, a wide viewing angle, and a high yield.

A method according to another preferred embodiment of the present invention for manufacturing a substrate including a laminate structure in which a plurality of conductive layers are laminated, includes the steps of forming a first conductive layer which is provided in the laminate structure and contains zinc oxide as a main component; and forming a second conductive layer which is positioned in a surface in contact with a substance used in a chemical treatment carried out to form the conductive layers and which is made of material less likely to be eroded by the substance than the zinc oxide.

According to the above-described preferred embodiment of the present invention, even though the first conductive layer containing economically accessible zinc oxide as a main component is preferably used, it is possible to prevent the first conductive layer from being eroded by the chemical treatment carried out to form the conductive layers. That is, the second conductive layer which is in contact with the substance used in the chemical treatment is less likely to be eroded by the substance than zinc oxide, and the first conductive layer is not in contact with the substance, so that the first conductive layer is hardly eroded. Thus, the manufacturing method is effective in (i) including a step of etching the conductive layers by using a patterned photosensitive resist as a mask, and (ii) including a step of patterning a photosensitive resist so as to form the patterned photosensitive resist on a conductive layer.

A method according to another preferred embodiment of the present invention for manufacturing a substrate including conductive layers, includes the steps of forming the conductive layers on the substrate; forming a photosensitive resist on the substrate so that the photosensitive resist is positioned on the side of the conductive layers; and patterning the photosensitive resist by exposing the photosensitive resist and developing the photosensitive resist with a developer, wherein the step of forming the conductive layers includes at least the sub-steps of: forming a first conductive layer containing zinc oxide on the substrate; and forming a second conductive layer having a surface on which the photosensitive resist is formed, said second conductive layer being made of material which is less likely to be eroded by the developer than the zinc oxide.

According to the above-mentioned preferred embodiment of the present invention, even though the first conductive layer containing economically accessible zinc oxide as a main component is preferably used, the first conductive is hardly eroded by the developer in developing the photosensitive resist. Thus, the manufacturing method is effective in (i) a case of etching the conductive layers by using a patterned photosensitive resist as a mask, and (ii) a case of patterning a photosensitive resist so as to form the patterned photosensitive resist on a conductive layer. Further, a layer containing zinc oxide as a main component in a region where the resist pattern is fractured by erroneous application and exposure of the resist at the time of photolithography is hardly eroded by the developer after the exposure. Further, in a substrate used in an MVA type liquid crystal display device, the second conductive layer exists in forming a vertical alignment controlling protrusion with the photosensitive resist, so that it is possible to suppress the layer whose main component is zinc oxide from being eroded by the developer.

The method according to a preferred embodiment of the present invention for manufacturing the substrate further includes the steps of checking a shape obtained by patterning the photosensitive resist; and peeling the photosensitive resist with a peeling agent when the shape is determined to be unfavorable as a result of the check, wherein the second conductive layer is made of material less likely to be eroded by the peeling agent than the zinc oxide.

According to the above-mentioned preferred embodiment of the present invention, the layer whose main component is zinc oxide is hardly eroded by the peeling agent at the time of photo rework.

A method according to a preferred embodiment of the present invention for manufacturing a substrate including conductive layers, includes the steps of forming the conductive layers on the substrate; forming a photosensitive resist on the substrate so that the photosensitive resist is positioned on the side of the conductive layers; patterning the photosensitive resist; patterning the conductive layers by etching, with an etchant, the photosensitive resist having been patterned; and peeling, with a peeling agent, the photosensitive resist from the substrate whose conductive layers have been patterned, wherein the step of forming the conductive layers includes at least the sub-steps of forming a first conductive layer containing zinc oxide on the substrate; and forming a second conductive layer having a surface on which the photosensitive resist is formed, said second conductive layer being made of material which is less likely to be eroded by the peeling agent than the zinc oxide.

According to the above-described preferred embodiment of the present invention, even though the first conductive layer containing economically accessible zinc oxide as a main component is preferably used, it is possible to suppress the layer whose main component is zinc oxide from being eroded by the peeling agent in a step of peeling the resist pattern with the peeling agent.

The method according to a preferred embodiment of the present invention for manufacturing the substrate is arranged so that the conductive layers are etched with the same etchant and in the same step in patterning the conductive layers.

According to various preferred embodiments of the present invention, it is possible to manufacture the substrate without increasing the number of steps required in etching the conductive layers.

Note that, in the present specification, “erosion” means a state in which at least a part of the conductive layers is eroded by liquid such as the developer and the peeling agent. A state indicated by the wording “less likely to be eroded” means durability against the erosion.

According to various preferred embodiments of the present invention, even though the first conductive layer containing economically accessible zinc oxide as a main component is preferably used, the first conductive layer is hardly eroded by at least either the developer or the peeling agent due to the presence of the second conductive layer which is less likely to be eroded by at least either the developer or the peeling agent. Thus, preferred embodiments of the present invention are effective in being applied to (i) a substrate in which a photosensitive resist is applied and conductive layers are etched by using a patterned photosensitive resist as a mask, and (ii) a substrate in which a photosensitive resist is formed on a conductive layer through patterning. Therefore, it is possible to stably provide a substrate at the low cost while preventing the yield and quality from being impaired.

Other features, elements, processes, steps, characteristics and advantages of the present invention will become more apparent from the following detailed description of preferred embodiments of the present invention with reference to the attached drawings.

### BRIEF DESCRIPTION OF DRAWINGS

FIG. 1 is a cross sectional view schematically illustrating an arrangement of a first preferred embodiment of a display device substrate (active matrix substrate) for a liquid crystal display device according to the present invention.

FIG. 2 is a plan view schematically illustrating an arrangement of a pixel and a peripheral portion thereof in the display device active matrix substrate of the first preferred embodiment of the present invention.

FIG. 3 is a cross sectional view taken along an A1-A2 line of the display device substrate illustrated in FIG. 2.

FIG. 4 is a cross sectional view schematically illustrating an arrangement of a second preferred embodiment of a display device substrate (color filter substrate) in the liquid crystal display device according to the present invention.

FIG. 5 is a plan view schematically illustrating a pixel and a peripheral portion thereof in the display device color filter substrate of the second preferred embodiment of the present invention.

FIG. 6 is a cross sectional view taken along a B1-B2 line of the display device substrate illustrated in FIG. 5.

FIG. 7 is a schematic plan view illustrating a fracture of a pixel electrode in a Comparative Example.

FIG. 8 is a cross sectional view taken along a C1-C2 of FIG. 7 so as to schematically illustrate the pixel electrode of the Comparative Example.

FIG. 9 is a plan view illustrating a conventional display device active matrix substrate.

FIG. 10 is a cross sectional view taken along a D1-D2 of the display device substrate illustrated in FIG. 9.

FIG. 11 is a plan view illustrating a conventional display device color filter substrate.

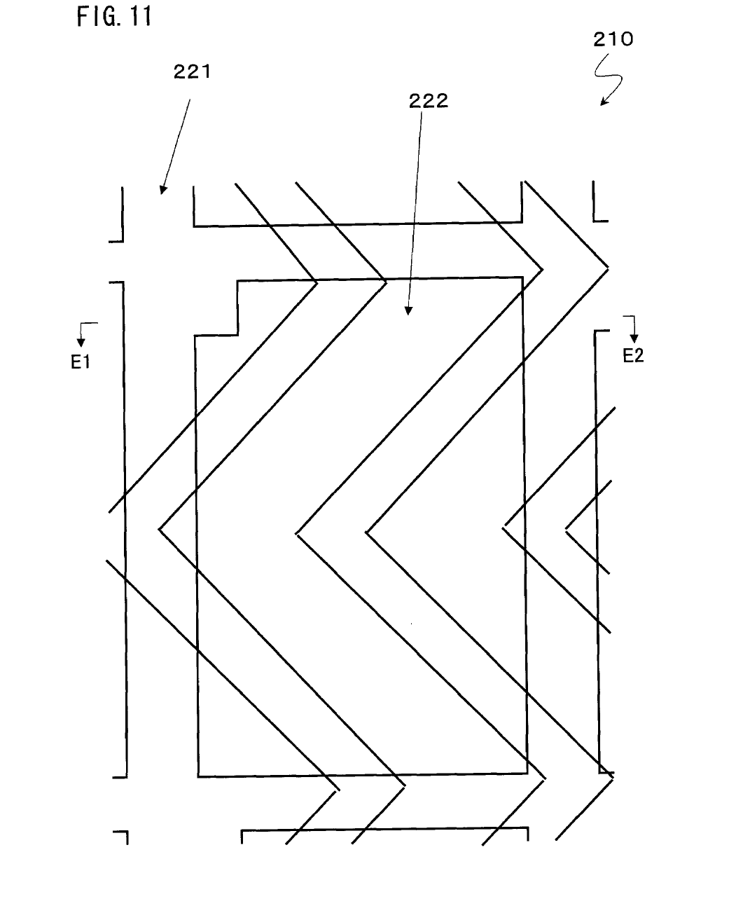

FIG. 12 is a cross sectional view taken along an E1-E2 line of the display device substrate illustrated in FIG. 11.

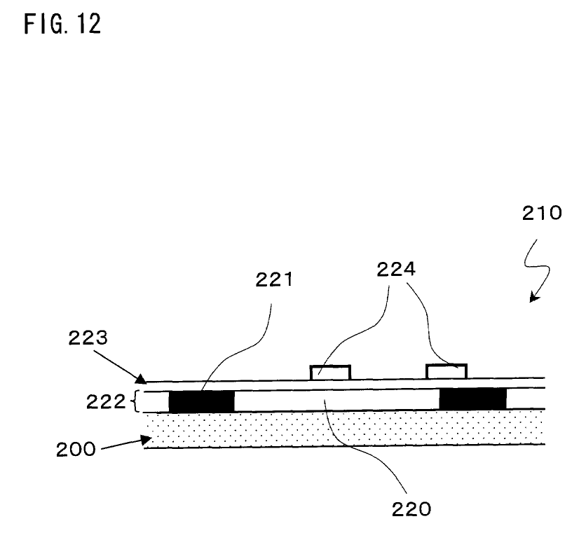

### DETAILED DESCRIPTION OF PREFERRED EMBODIMENTS

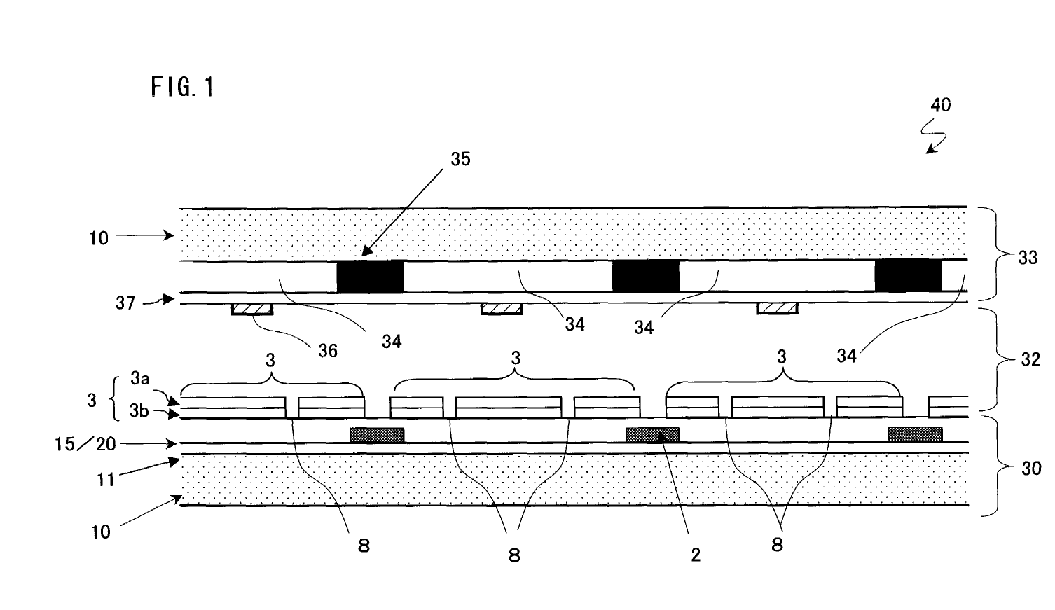

The following describes a preferred embodiment of the present invention with reference to FIG. 1 to FIG. 3.

Note that, in the present preferred embodiment, an active matrix substrate for a liquid crystal display device is described as a specific example of the display device substrate.

FIG. 1 is a cross sectional view illustrating an example of the liquid crystal display device using the active matrix substrate according to a preferred embodiment of the present invention. A liquid crystal display device 40 includes an active matrix substrate 30 and a color filter substrate 33. These substrates sandwich a liquid crystal layer 32 made of liquid crystal such as vertical alignment liquid crystal. The active matrix substrate 30 includes pixel electrodes 3 (laminate structure) each of which is arranged so that a zinc oxide (ZnO) layer 3b (first conductive layer) and an ITO layer 3a (second conductive layer) are laminated. The color filter substrate 33 includes: a color filter layer having coloring layers 34 and light shielding films 35; protrusions (protrusions for controlling alignment) 36 for controlling pre-tilt of liquid crystal molecules so as to control alignment of liquid crystal; and a transparent electrode 37.

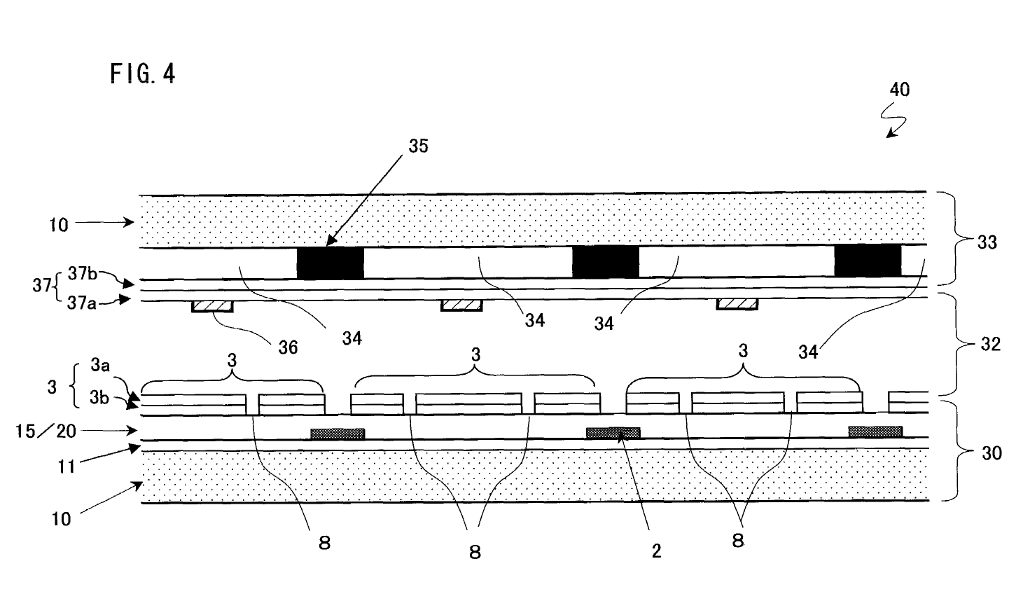

Note that, it is preferable that, as illustrated in FIG. 4, the transparent electrode 37 is a laminate structure in which the ZnO layer 37b (first conductive layer) and the ITO layer 37a (second conductive layer) are laminated. Further, the liquid crystal layer 32 is sandwiched by an alignment film (not shown) of the counter substrate (color filter substrate) 33 and an alignment film (not shown) of the active matrix substrate 30.

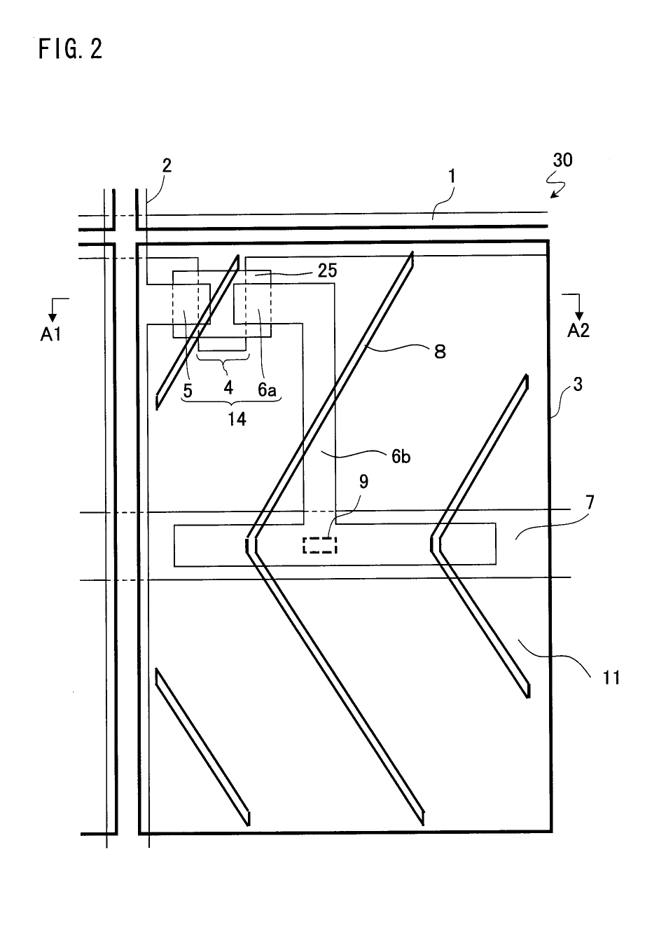

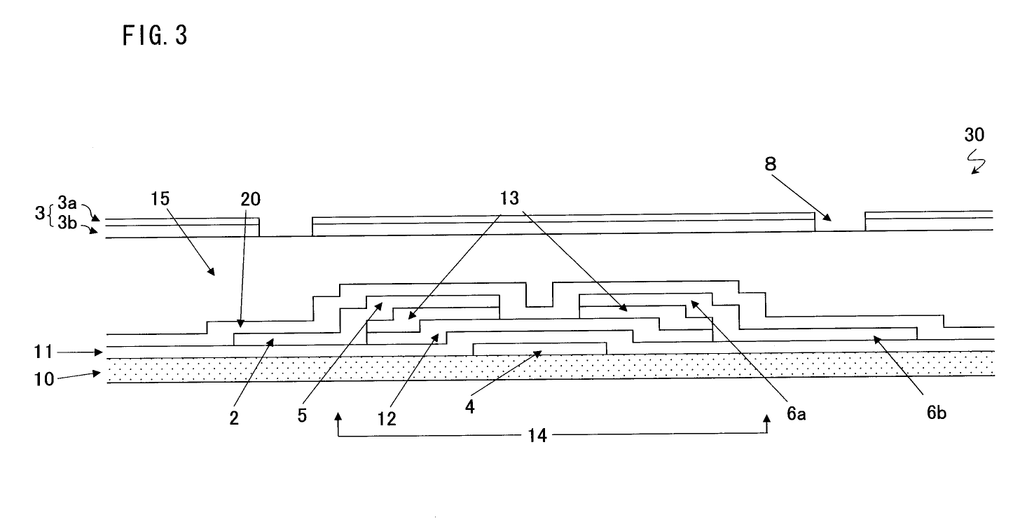

FIG. 2 is a plan view illustrating a pixel and a part of a pixel adjacent to that pixel in the active matrix substrate 30 (display device substrate) according to a preferred embodiment of the present invention. As illustrated in FIG. 2 and FIG. 3, the source line (signal line) 2, the gate line (scanning line) 1, and the pixel electrode 3 are laminated on and above the insulating substrate 10. The gate line 1 and the source line 2 are disposed so as to intersect each other. Further, at a junction of the gate line 1 and the source line 2, a switching element (TFT) 14 and the pixel electrode 3 are provided. Note that, the insulating substrate 10 is positioned in a backmost side in FIG. 2 and is positioned as illustrated in the cross sectional view of FIG. 3. Note that, FIG. 3 is the cross sectional view taken along the A1-A2 line of FIG. 2.

A gate electrode 4 is connected to the gate line 1. A source electrode 5 is connected to the source line 2. Further, in FIG. 3, the pixel electrode 3 is arranged so that the ZnO layer 3b serving as a lower layer and the ITO layer 3a serving as an upper layer are laminated. The pixel electrode 3 is connected to a drain electrode 6a via a contact hole 9 provided on an interlayer insulating film 15 and a drain leading electrode 6b. Further, a slit 8 for controlling alignment of liquid crystal is provided on the pixel electrode 3. Further, the drain leading electrode 6b is provided opposite to an auxiliary capacitor bus line 7 with a gate insulating film 11 therebetween so as to constitute an auxiliary capacitor.

Next, the following briefly describes control of a current and a voltage. When the gate line 1 is selected, a voltage is applied to the gate electrode 4. The voltage applied to the gate electrode 4 causes a current flowing between the source electrode 5 and the drain electrode 6a to be controlled. That is, in accordance with a signal transmitted from the source line 2, a current flows from the source electrode 5 to the drain electrode 6a, and a current flows from the drain electrode 6a via the drain leading electrode 6b to the pixel electrode 3. As a result, the pixel electrode 3 applies a voltage to the liquid crystal layer 32 so as to carry out a predetermined display. The auxiliary bus line 7 is arranged in a subsidiary manner so as to keep the predetermined display.

Next, the following describes a method for manufacturing the active matrix substrate 30 with reference to FIG. 2 and FIG. 3.

First, a laminate film made of Ti/Al/Ti is formed on the insulative substrate 10 made of transparent insulator such as glass by sputtering, and photolithography is carried out, and dry etching and resist peeling are carried out, thereby simultaneously forming the gate line 1, the gate electrode 4, and the auxiliary capacitor line 7.

Next, the gate insulating film 11 made of SiNx (silicon nitride film) whose thickness ranges from about 3000 Å to about 5000 Å, the active semiconductor layer 12 made of amorphous silicon whose thickness ranges from about 1500 Å to about 3000 Å, and a phosphor-doped n-type low-resistance semiconductor layer 13 whose thickness ranges from about 500 Å to about 1000 Å are formed on and above a surface thereof, and photolithography, dry-etching, and resist peeling are carried out so as to form an island-shaped semiconductor layer 25, for example.

Herein, a mixture gas obtained by mixing SiH₄ gas, NH₃ gas, and N₂ gas is used to form the gate insulating film 11, and a mixture gas obtained by mixing SiH₄ gas and H₂ gas is used to form the active semiconductor layer 12, and a mixture gas obtained by mixing SiH₄ gas, PH₃ gas, and H₂ gas is used to form the n-type low-resistance semiconductor layer 13. These layers are sequentially formed by CVD (Chemical Vapor Deposition).

Further, a laminate film made of Ti/Al/Ti is formed by sputtering, and photolithography is carried out, and dry-etching is carried out, thereby simultaneously forming the source line 2, the source electrode 5, the drain electrode 6a, and the drain leading electrode 6b. Subsequently, the n-type semiconductor layer 13 is etched so as to be divided into a source and a drain, and the resist is peeled off. At this time, the thin film transistor (TFT) is formed.

Next, the lower layer insulating film 20 made of SiNx whose thickness ranges from about 1000 Å to about 5000 Å is formed so as to cover the entire surface by using a mixture gas, made of SiH₄ gas and N₂ gas, in accordance with CVD.

Thereafter, the upper layer organic insulating film 15 made of positive photosensitive acryl resin whose thickness ranges from about 2 μm to about 4 μm is formed by photolithography so as to have a contact pattern for the contact hole 9 and the gate line leading-out terminal and a contact pattern for the source line leading-out terminal.

Next, in order to form the contact hole 9, the gate line leading-out terminal, and the source line leading-out terminal, the lower interlayer insulating film 20 and the gate insulating film 11 are sequentially etched by means of dry etching with a mixture gas made of CF₄ gas and O₂ gas by using the upper layer organic insulating film 15 as a mask.

Thereafter, the ZnO film and the ITO film are formed by sputtering so as to coat the contact hole 9. First, the ZnO film is formed, with a sputtering device adopting an RF power supply, at power of about 15 kW, a substrate temperature of about 210° C., and a pressure of about 1.2 Pa, by using a mixture gas made of Ar and O₂ (Ar flow volume:O₂ flow volume=2 to 3:1), so as to have a thickness of about 900 Å, for example. Next, with a sputtering device adopting a DC power supply, the ITO film is formed at a room temperature, power of about 25 kW, and a pressure of about 1.2 Pa, by using a mixture gas made of Ar, O₂, and H₂O (Ar flow volume:O₂ flow volume:H₂O flow volume=20:1:1 to 2), so as to have a thickness of about 200 Å, for example. Further, a photosensitive resist is applied, and the photosensitive resist is exposed by photolithography, and then the exposed photosensitive resist is developed with developer. Further, a pattern formed by the patterning is used as a mask so as to pattern the ZnO film and the ITO film, that have been formed, by wet etching with etchant made of phosphoric acid, nitric acid, and acetic acid. Thereafter, the resist is peeled with a peeling agent, thereby forming the pixel electrode 3. Note that, in the present preferred embodiment, aqueous solution in which concentration of TMAH (tetramethylammonium hydroxide) is 10% or less is preferably used as the developer. Further, a mixture liquid made of MEA (monoethanolamine) and DMSO (dimethylsulfoxide) (mixture ratio is MEA:DMSO=2 to 3:1) is preferably used as the peeling agent. Further, in the etching step, both the ZnO film and the ITO film are preferably etched in the same etching step and by using the same etchant.

In this manner, the active matrix substrate 30 of the present preferred embodiment is obtained. The active matrix substrate 30 and the color filter substrate 33 are combined with each other so that both the substrates are opposite to each other, and liquid crystal is injected into a gap between both the substrates, thereby manufacturing the liquid crystal panel. Further, drivers and the like are connected to leading-out terminals of the liquid crystal panel, thereby manufacturing the liquid crystal display device 40.

In the present preferred embodiment, a material used for the gate line 1 and the source line 2 preferably is Ti/Al/Ti. However, any metal may be used as the material for the gate line 1 and the source line 2 as long as a desired line resistance can be obtained. For example, metal such as tantalum (Ta), titanium (Ti), chromium (Cr), aluminum (Al), and the like and alloy thereof may be used as the material for the gate line 1 and the source line 2. Further, a film made of a laminate structure of TaN/Ta/TaN can be used as the material for the gate line 1 and the source line 2. Further, not only a generally used metallic film but also a transparent conductive film such as ITO can be used as the material for the source line 2.

In the present preferred embodiment, the slit is preferably provided so as to control pre-tilt of liquid crystal molecules. However, as in the alignment controlling protrusion provided on the color filter substrate, an alignment controlling protrusion using a photosensitive resist may be provided instead of providing the slit. Note that, the color filter substrate on which the alignment controlling protrusion is provided will be detailed later. Note that, a phenol novolak resin or the like is preferably used in forming the photosensitive resist.

Further, in the present preferred embodiment, an amorphous silicon thin film transistor is used in forming the switching element (TFT) 14. However, as the switching element 14, it is possible to use a microcrystal silicon thin film transistor, a polysilicon thin film transistor, a CG silicon (continuous grain boundary crystal silicon) thin film transistor, and MIM (Metal Insulator Metal) for example.

Further, in the pixel electrode 3, the ZnO layer 3b serving as a lower layer of the laminate film and the ITO layer 3a serving as an upper layer are preferably used. However, any arrangement is possible as long as it is possible to prevent the pixel electrode 3 from being eroded by the developer after exposing the lower ZnO layer 3 in the photolithography step or from being eroded by the peeling agent in peeling the resist at the time of photo rework and in peeling the resist after etching the pixel electrode. Thus, instead of the ITO layer 3a, an electrode material such as IZO, InO, TiO can be used as the upper layer of the laminate structure. Further, the thickness of the ITO layer 3a is preferably about 200 Å, but the ITO layer 3a may be thinner than about 200 Å as long as it is possible to prevent the pixel electrode 3 from being eroded by the developer after exposing the lower ZnO layer 3 in the photolithography step or from being eroded by the peeling agent in peeling the resist at the time of photo rework and in peeling the resist after etching the pixel electrode. Further, in the pixel electrode 3 of the present preferred embodiment, ZnO is preferably used in forming the conductive layer containing zinc oxide as a main component, but diverse elements such as Al and Ga may be contained in ZnO as dopant. By doping these elements and the like, it is possible to realize lower resistance.

In addition, the pixel element 3 is not limited to the two-layered film but may be a two-or-more-layered film.

Further, in forming the upper interlayer insulating film 15, a positive acrylic photosensitive transparent resin is preferably used, but a material for the upper interlayer insulating film 15 is not limited to this. As the material for the upper interlayer insulating film 15, it is possible to use a material which allows for a desired dielectric constant, transmittance, and selection ratio in etching the lower interlayer insulating film 15 and the gate insulating film 11, e.g., a negative photosensitive resin, SiO₂ (silicon dioxide), and the like. Further, in forming the lower interlayer insulating film 20, the SiNx film formed by CVD is preferably used, but a positive or negative photosensitive transparent resin may be used. Further, also as to the protection film, not only the SiNx film but also the photosensitive transparent resin and the SiO₂ film is usable likewise. Note that, examples of the photosensitive transparent resin include acryl resin, epoxy resin, polyurethane resin, polyimide resin, and the like.

Note that, in the pixel electrode 3 and the interlayer insulating films, the term “lower” refers to a layer positioned on the side of the insulating substrate 10, and the term “upper” refers to a layer positioned on the side of the liquid crystal layer 32.

Next, with reference to FIG. 3, the following describes an effect for preventing display failure caused by such a condition that a predetermined voltage is not applied to the liquid crystal layer 32 due to insufficient application of the resist in the photolithography step at the time of formation of the pixel electrode 3.

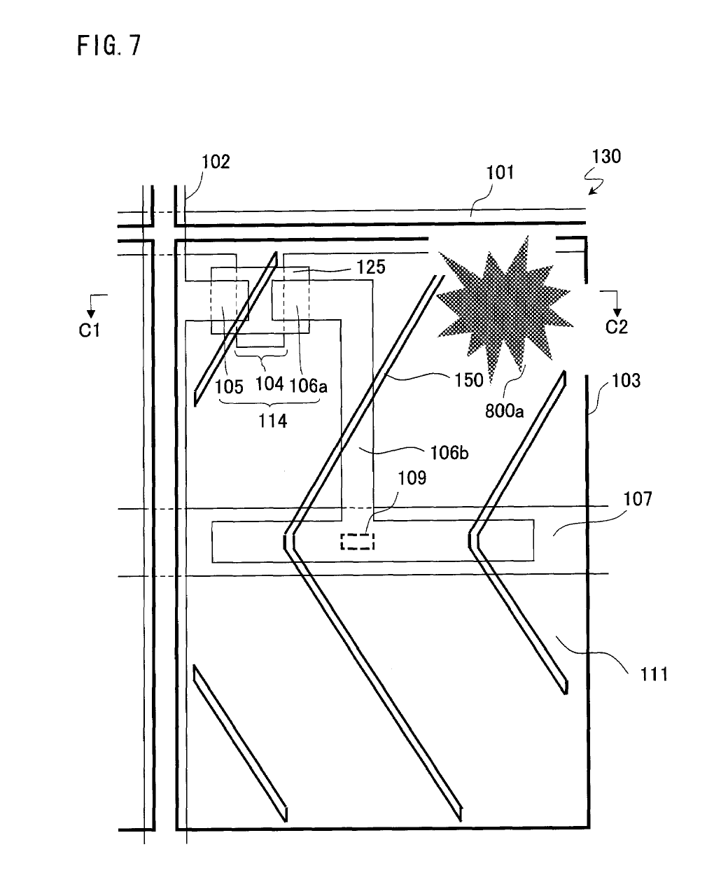

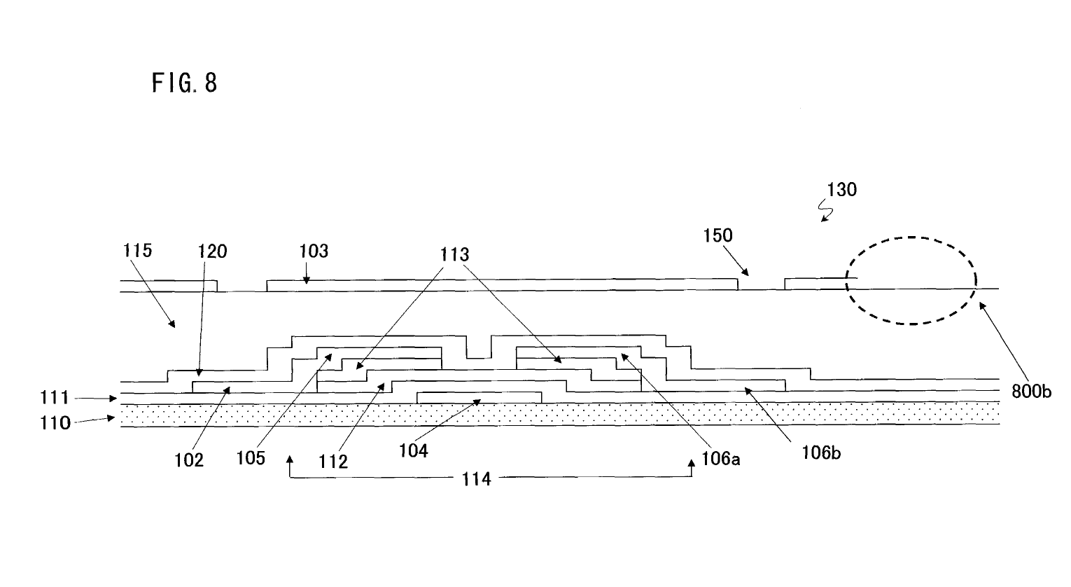

FIG. 7 is a plan view schematically illustrating, as a comparative example, a state in which a pixel electrode 103 made of ZnO is eroded by a peeling agent, at the time of photo rework, due to a resist defect 800a. Further, FIG. 8 is a cross sectional view taken along a C1-C2 line of FIG. 7 and schematically illustrating a portion including a pixel electrode fracture 800b.

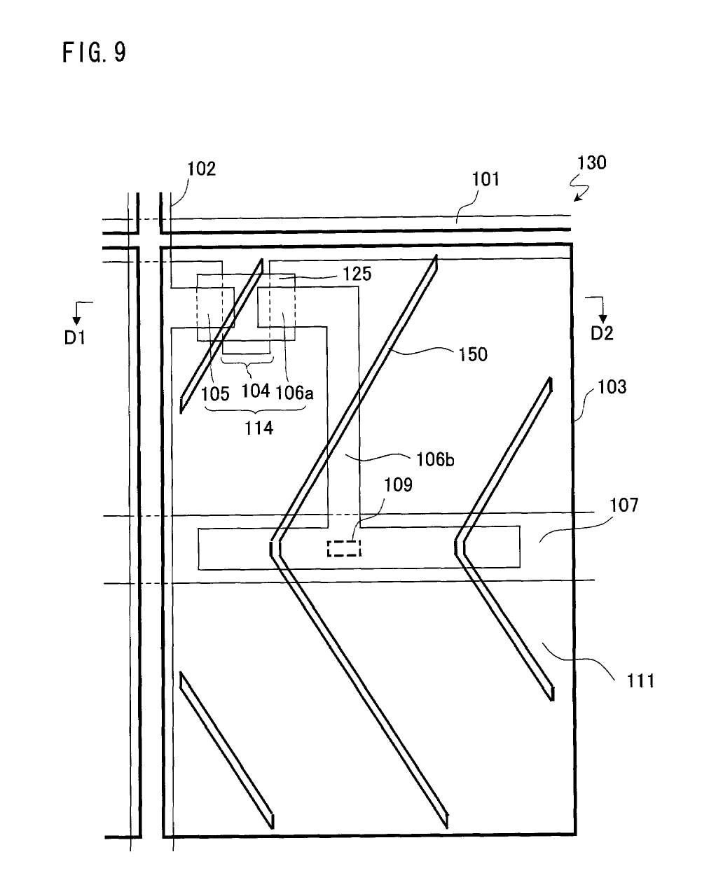

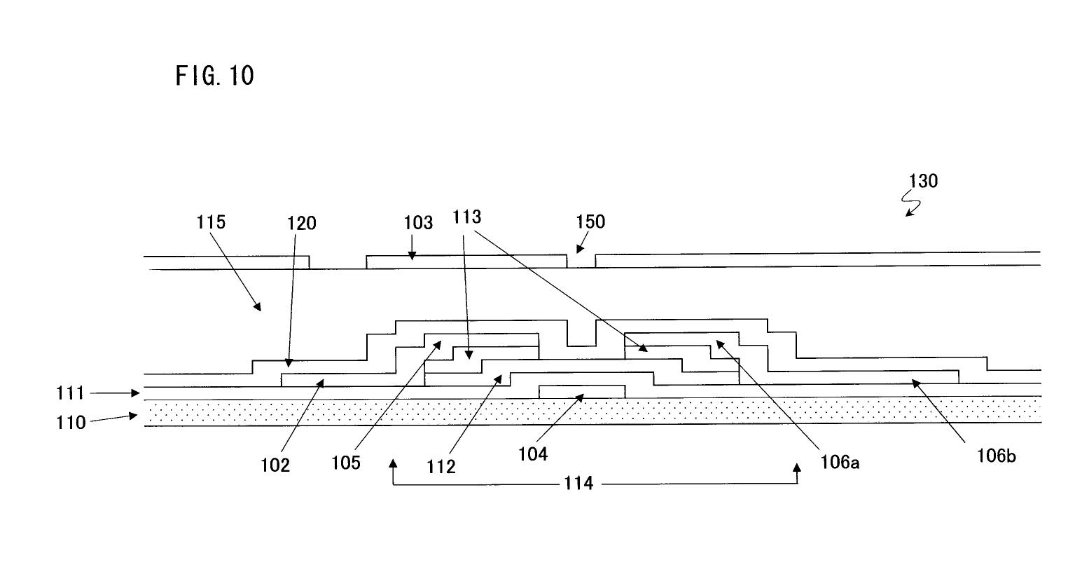

A foreign substance included in applying the resist so as to form the film causes the resist to drop off (fracture) or an insufficient adhesive force at the time of the resist application and film formation causes the resist to drop off (fracture), which results in the resist defect 800a. In this case, the pixel electrode 103 made of ZnO is eroded at a position where the resist is fractured at the time of photo rework. Thus, as illustrated in FIG. 8, the pixel electrode 103 is fractured, so that a portion which does not allow a predetermined voltage to be applied to the liquid crystal layer occurs in the pixel electrode fracture 800b. In addition, as apparent from FIG. 7, also an alignment controlling slit 150 is partially fractured. Thus, liquid crystal molecules are not regularly aligned, which results in a pixel defect. This causes the display quality and the yield to be impaired. However, according to the present preferred embodiment, the ITO layer 3a preferably is additionally formed on the ZnO layer 3b constituting the pixel electrode 3 as illustrated in FIG. 3, so that the ITO layer 3a serves as a protection film at the time of photo rework. This prevents the pixel electrode 3 from being fractured, so that the pixel is free from any defect. Note that, in FIG. 7 and FIG. 8, portions corresponding to the conventional art described with FIG. 9 and FIG. 10 are numbered in the same manner as in the conventional art.

Herein, the photo rework step is carried out as follows. That is, after forming the resist by carrying out exposure and development in the photolithography step so as to have the pixel electrode pattern, whether there is any resist fracture or not is checked by using a defect inspecting device. In case where the resist fracture is found by the inspecting device, the patterned resist is peeled with a peeling agent. Further, the photolithography step is carried out again so as to form a resist pattern. At the time of photo rework, it is possible to use the same peeling agent as in the photolithography step. In the present preferred embodiment, a mixture solution made of MEA (monoethanol amine) and DMSO (dimethylsulfoxide) is preferably used (mixture ratio is MEA:DMSO=2 to 3:1).

Note that, the display device is not limited to the liquid crystal display device. For example, it is possible to arrange an organic EL display device by providing the active matrix substrate 30 of the present preferred embodiment and the color filter substrate 33 so that both the substrates are opposite to each other and an organic EL layer is provided between both the substrates so as to form an organic EL panel and by connecting drivers and the like to leading-out terminals of the organic EL panel.

The following describes another preferred embodiment of the present invention with reference to FIG. 4 to FIG. 6. Note that, in the present preferred embodiment, a color filter 33 for a liquid crystal display device is described as a specific example of the display device substrate. The present preferred embodiment describes an example where the present invention is applied to the color filter substrate on which an alignment controlling protrusion for regionally controlling alignment (pre-tilt) of liquid crystal molecules in the pixel is provided. Note that, the present preferred embodiment describes a case where a black matrix is provided on the color filter substrate 33, but the present invention is applicable also to an arrangement in which the black matrix is not provided. For convenience in description, the same reference numerals are given to members having the same functions as members illustrated in FIG. 1.

FIG. 4 is a cross sectional view illustrating an example of a liquid crystal display device according to the present preferred embodiment of the present invention. The liquid crystal display device 40 includes an active matrix substrate 30 and a color filter substrate 33. These substrates sandwich a liquid crystal layer 32 made of liquid crystal such as vertical alignment liquid crystal. The active matrix substrate 30 includes pixel electrodes 3 each of which is arranged so that a ZnO layer 3b and an ITO layer 3a are laminated. The color filter substrate 33 includes: a color filter layer having coloring layers 34 and light shielding films 35; protrusions (protrusions for controlling alignment) 36 for controlling pre-tilt of liquid crystal molecules so as to control alignment of liquid crystal; and a transparent electrode 37 in which a ZnO layer 37b and an ITO layer 37a are laminated. Note that, the liquid crystal layer 32 is sandwiched by an alignment film (not shown) of the counter substrate (color filter substrate) 33 and an alignment film (not shown) of the active matrix substrate 30.

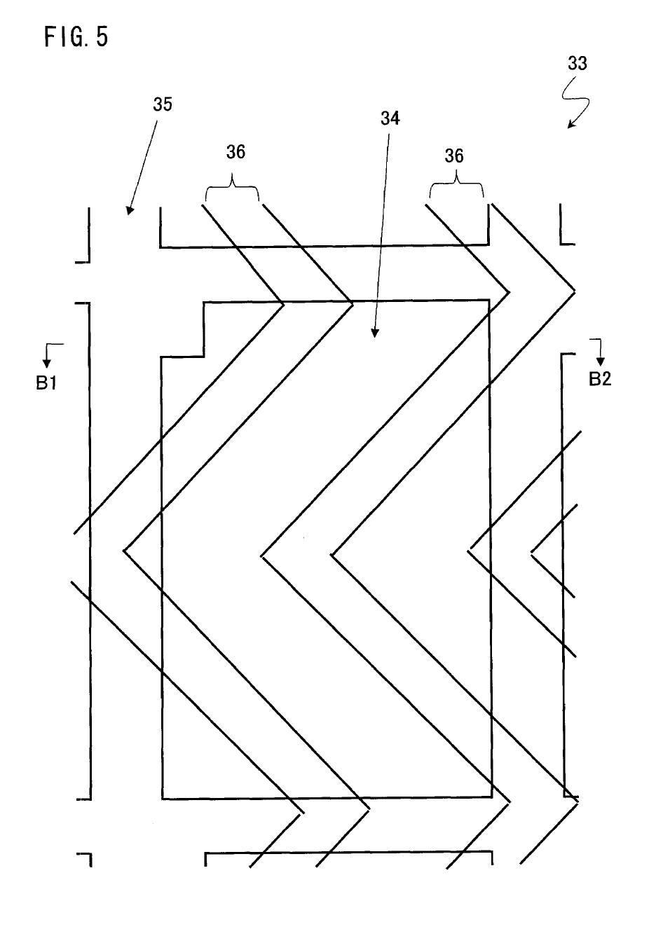

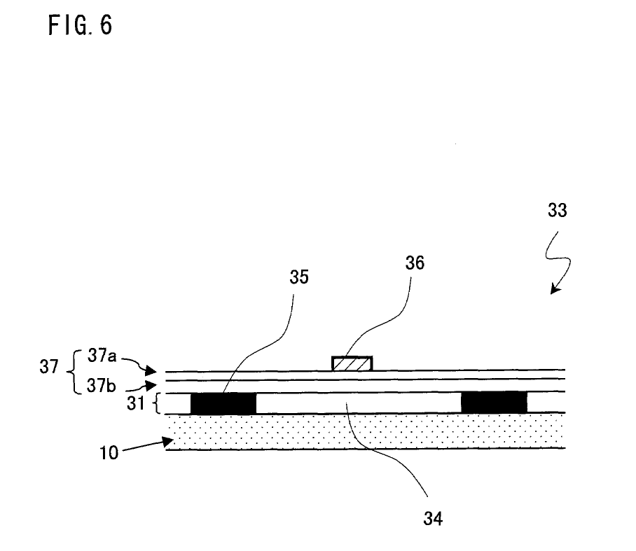

FIG. 5 is a plan view illustrating a pixel and a part of a pixel adjacent to that pixel in the color filter substrate 33 according to a preferred embodiment of the present invention. FIG. 6 is a cross sectional view taken along a B1-B2 line of FIG. 3 so as to illustrate the color filter substrate 33.

The color filter substrate 33 is typically arranged so as to include: a color filter layer 31 constituted of a three-primary-color (red, green, and blue) layer 34, a BM35, and the like; a counter electrode (transparent electrode) 37 in which the ZnO layer 37b and the ITO layer 37a are laminated; an alignment film (not shown); and a protrusion 36 for controlling alignment, wherein these members are formed on a transparent substrate 10. Note that, the transparent substrate 10 is positioned in a backmost side in FIG. 5 and is positioned as illustrated in the cross sectional view of FIG. 6.

The following describes a method for manufacturing the color filter substrate 33 of the present preferred embodiment.

On the transparent substrate, a negative acrylic photosensitive resin liquid or the like in which carbon fine particles have been dispersed is applied by spin coating, and then the resultant is dried, so as to form a black photosensitive resin layer. Subsequently, the black photosensitive resin layer is exposed via a photo mask, and then the resultant is developed, so as to form the BM35 whose thickness is about 2.0 μm, for example. At this time, on a region where a first coloring layer (e.g., a red layer) is to be formed, a first coloring layer opening is formed. On a region where a second coloring layer (e.g., a green layer) is to be formed, a second coloring layer opening is formed. On a region where a third coloring layer (e.g., a blue layer) is to be formed, a third coloring layer opening is formed. In this manner, the BM35 is formed. Note that, the openings are formed so as to respectively correspond to the pixel electrodes of the active matrix substrate.

Next, a negative acrylic photosensitive resin liquid in which dye has been dispersed is applied by spin coating, and then the resultant is dried, and exposure and development are carried out by using a photo mask, so as to form a red layer whose thickness is about 2.0 μm, for example.

Thereafter, the same operation is carried out with respect to the second coloring layer (e.g. green layer) and the third coloring layer (e.g., blue layer), thereby completing formation of the color filter layer 31.

Further, the laminated transparent electrode 37 whose lower layer is the ZnO layer 37b and upper layer is the ITO layer 37a is formed by means of sputtering. First, the ZnO film is formed, with a sputtering device adopting an RF power supply, at power of about 15 kW, a substrate temperature of about 210° C., and a pressure of about 1.2 Pa, by using a mixture gas made of Ar and O₂ (Ar flow volume:O₂ flow volume=2 to 3:1), so as to have a thickness of about 900 Å, for example. Next, with a sputtering device adopting a DC power supply, the ITO film is formed at a room temperature, power of about 25 kW, and a pressure of about 1.2 Pa, by using a mixture gas made of Ar, O₂, and H₂O (Ar flow volume:O₂ flow volume:H₂O flow volume=20:1:1 to 2), so as to have a thickness of about 200 Å, for example.

Next, a positive phenol novolak photosensitive resin liquid is applied by spin coating, and the resultant is dried, and exposure is carried out by using a photo mask, and development is carried out by using a TMAH developer, thereby forming a vertical alignment controlling protrusion 36 whose thickness is about 1.5 μm, for example. In this manner, the color filter substrate 33 is formed. The active matrix substrate 30 and the color filter substrate 33 are combined with each other so that both the substrates are opposite to each other, and liquid crystal is injected into a gap between both the substrates, thereby manufacturing the liquid crystal panel. Further, drivers and the like are connected to leading-out terminals of the liquid crystal panel, thereby manufacturing the liquid crystal display device 40.

According to the present preferred embodiment adopting the foregoing arrangement, the ITO layer 37a is additionally formed on the ZnO layer 37b constituting the transparent electrode 37 as illustrated in FIG. 6, so that the ITO layer 37a serves as a protection film at the time of photo rework carried out with respect to the alignment controlling protrusion. This prevents the transparent electrode 37 from being eroded, so that the pixel is free from any display failure. In addition, ZnO existing on a region other than the vertical alignment controlling protrusion is not eroded by the developer, so that the transparent electrode 37 is not eroded. As a result, the display device is free from any display failure.

In the transparent electrode 37 of the present preferred embodiment, the ZnO layer is used in forming the conductive layer containing zinc oxide as a main component, but diverse elements such as Al and Ga may be contained in ZnO as dopant. By doping these elements and the like, it is possible to obtain a transparent electrode having a lower resistance.

Note that, in the transparent electrode 37, the term “lower” refers to a layer positioned on the side of the insulating substrate 10, and the term “upper” refers to a layer positioned on the side of the liquid crystal layer 32.

Further, as in the pixel electrode of the active matrix, a slit pattern for controlling alignment of liquid crystal molecules may be provided instead of the vertical alignment controlling protrusion 36 provided on the color filter substrate 33 of the MVA type. In this case, the slit can be provided on the transparent electrode 37 in the same manner as formation of the slit 8 on the pixel electrode 3 of the active matrix substrate 30 described in the first preferred embodiment. That is, first, the ZnO film and the ITO film are formed by sputtering, and then a photosensitive resist is applied, and the photosensitive resist is exposed by photolithography, and then the exposed photosensitive resist is developed with a developer. Further, a pattern formed by the patterning is used as a mask so as to pattern the ZnO film and the ITO film, that have been formed, by wet etching with etchant made of phosphoric acid, nitric acid, and acetic acid. Thereafter, the resist is peeled with a peeling agent, thereby forming the transparent electrode 37. Note that, also in the present preferred embodiment, aqueous solution in which concentration of TMAH (tetramethylammonium hydroxide) is 10% or less is preferably used as the developer. Further, a mixture liquid made of MEA (monoethanolamine) and DMSO (dimethylsulfoxide) (mixture ratio is MEA:DMSO=2 to 3:1) is preferably used as the peeling agent. Further, in the etching step, both the ZnO film and the ITO film preferably are etched in the same etching step and by using the same etchant.

Further, in the transparent electrode 37, the ZnO layer 37b serving as a lower layer of the laminate film and the ITO layer 37a serving as an upper layer are preferably used. However, any arrangement is possible as long as it is possible to prevent the transparent electrode 37 from being eroded by the developer after exposing the lower ZnO layer 37b in the photolithography step or from being eroded by the peeling agent in peeling the resist at the time of photo rework and in peeling the resist after etching the pixel electrode. Thus, instead of the ITO layer 37a, an electrode material such as IZO, InO, TiO can be used as the upper layer of the laminate structure. Further, the thickness of the ITO layer 37a preferably is about 200 Å, but the ITO layer 37a may be thinner than about 200 Å as long as it is possible to prevent the transparent electrode 37 from being eroded by the developer after exposing the lower ZnO layer 37b in the photolithography step or from being eroded by the peeling agent in peeling the resist at the time of photo rework and in peeling the resist after etching the pixel electrode.

In addition, the transparent electrode 37 is not limited to the two-layered film but may be a three-or-more-layered film.

Further, in the present preferred embodiment, the active matrix substrate described in the first preferred embodiment preferably is used, but a substrate made only of an ITO layer may be used as the pixel electrode 3, for example. However, the effects and advantages of the present invention can be obtained in both the substrates, so that it is preferable to apply the present invention to both the substrates as in the present preferred embodiment.

Note that, the display device is not limited to the liquid crystal display device. For example, it is possible to arrange an organic EL display device by providing the active matrix substrate 30 and the color filter substrate 33 of the present preferred embodiment so that both the substrates are opposite to each other and an organic EL layer is provided between both the substrates so as to form an organic EL panel and by connecting drivers and the like to leading-out terminals of the organic EL panel.

Further, in the first and second preferred embodiments, the liquid crystal display device of MVA type is described, but the present invention is not limited to this. The present invention is applicable not only to the substrate of the aforementioned MVA liquid crystal display device but also to a substrate, having a transparent electrode conductive layer subjected to the lithography step, which is provided on a liquid crystal display device other than the MVA type, e.g., various display devices such as an EL display device and a plasma display device, a photoelectric transfer device such as a solar battery, and a touch panel.

Note that, the present invention can be realized according to the following arrangements.

A first arrangement of the substrate including a laminate structure in which a plurality of conductive layers including at least a first conductive layer containing zinc oxide as a main component, wherein a second conductive layer provided in the laminate structure so as to be positioned in a surface in contact with a substance used in a chemical treatment carried out to form the conductive layers is made of material which is less likely to be eroded by the substance than the zinc oxide.

A second arrangement based on the first arrangement, wherein the substance is a photosensitive resist developer used in a photolithography step for forming the conductive layers.

A third arrangement based on the first arrangement, wherein the substance is a photosensitive resist peeling agent used in a photolithography step for forming the conductive layers.

A fourth arrangement based on any one of the first to third arrangements, wherein the second conductive layer is made of ITO or IZO.

A fifth arrangement based on any one of first to fourth arrangements, wherein the first conductive layer is thicker than the second conductive layer.

A sixth arrangement based on any one of first to fifth arrangements, wherein each of the conductive layers serves as a pixel electrode so as to constitute an active matrix substrate.

A seventh arrangement based on any one of first to fifth arrangements, wherein each of the conductive layers serves as a transparent electrode so as to constitute a color filter substrate.

An eighth arrangement based on any one of first to seventh arrangements, wherein the second conductive layer of the laminate structure has an alignment controlling protrusion.

A ninth arrangement based on any one of first to eighth arrangements, wherein each of the conductive layers has a slit.

A tenth arrangement of a display device that includes the substrate based on any one of first to ninth arrangements.

An eleventh arrangement of a method for manufacturing a substrate that includes a laminate structure in which a plurality of conductive layers are laminated, the method including forming a first conductive layer which is provided in the laminate structure and contains zinc oxide as a main component; and forming a second conductive layer which is positioned in a surface in contact with a substance used in a chemical treatment carried out to form the conductive layers and which is made of material less likely to be eroded by the substance than the zinc oxide.

A twelfth arrangement based on the eleventh arrangement, further including the steps of forming a photosensitive resist on the substrate so that the photosensitive resist is positioned on the side of the conductive layers; and patterning the photosensitive resist by exposing the photosensitive resist and developing the photosensitive resist with a developer, wherein the second conductive layer is made of material less likely to be eroded by the developer than the zinc oxide.

A thirteenth arrangement based on the twelfth arrangement, further comprising the steps of checking a shape obtained by patterning the photosensitive resist; and peeling the photosensitive resist with a peeling agent when the shape is determined as being unfavorable as a result of the check, wherein the second conductive layer is made of material less likely to be eroded by the peeling agent than the zinc oxide.

A fourteenth arrangement based on the eleventh arrangement, further comprising the steps of forming a photosensitive resist on the substrate so that the photosensitive resist is positioned on the side of the conductive layers; patterning the photosensitive resist; patterning the conductive layers by etching, with an etchant, the photosensitive resist having been patterned; and peeling, with a peeling agent, the photosensitive resist from the substrate whose conductive layers have been patterned, wherein the second conductive layer is made of material less likely to be eroded by the peeling agent than the zinc oxide.

A fifteenth arrangement based on the fourteenth arrangement, wherein the conductive layers are etched with the same etchant and in the same step in patterning the conductive layers.

Various preferred embodiments of the present invention are favorably applicable to a substrate in which conductive layers are etched by using a patterned photosensitive resist as a mask so as to form a pattern. Particularly, various preferred embodiments of the present invention are favorably applicable to a substrate, used in a liquid crystal panel, which includes a pixel electrode or a transparent electrode.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-15. (canceled)

16: A substrate having a laminate structure comprising:
a plurality of conductive layers laminated on each other and including:
at least a first conductive layer containing zinc oxide as a main component; and
a second conductive layer provided in the laminate structure so as to be positioned in a surface in contact with a substance used in a chemical treatment carried out to form the conductive layers is made of material which is less likely to be eroded by the substance than the zinc oxide.

17: The substrate as set forth in claim 16, wherein the substance is a photosensitive resist developer used in a photolithography step for forming the conductive layers.

18: The substrate as set forth in claim 16, wherein the substance is a photosensitive resist peeling agent used in a photolithography step for forming the conductive layers.

19: The substrate as set forth in claim 16, wherein the second conductive layer is made of ITO or IZO.

20: The substrate as set forth in claim 16, wherein the first conductive layer is thicker than the second conductive layer.

21: The substrate as set forth in claim 16, wherein each of the conductive layers serves as a pixel electrode so as to constitute an active matrix substrate.

22: The substrate as set forth in claim 16, wherein each of the conductive layers serves as a transparent electrode so as to constitute a color filter substrate.

23: The substrate as set forth in claim 16, wherein the second conductive layer of the laminate structure has an alignment controlling protrusion.

24: The substrate as set forth in claim 16, wherein each of the conductive layers has a slit.

25: A display device, comprising the substrate as set forth in claim 16.

26: A method for manufacturing a substrate including a laminate structure in which a plurality of conductive layers are laminated, said method comprising the steps of:
forming a first conductive layer which is provided in the laminate structure and contains zinc oxide as a main component; and
forming a second conductive layer which is positioned in a surface in contact with a substance used in a chemical treatment carried out to form the conductive layers and which is made of material less likely to be eroded by the substance than the zinc oxide.

27: The method as set forth in claim 26, further comprising the steps of:
forming a photosensitive resist on the substrate so that the photosensitive resist is positioned on the side of the conductive layers; and
patterning the photosensitive resist by exposing the photosensitive resist and developing the photosensitive resist with a developer; wherein
the second conductive layer is made of material less likely to be eroded by the developer than the zinc oxide.

28: The method as set forth in claim 27, further comprising the steps of:
checking a shape obtained by patterning the photosensitive resist; and
peeling the photosensitive resist with a peeling agent when the shape is determined to be unfavorable as a result of the checking step; wherein
the second conductive layer is made of material less likely to be eroded by the peeling agent than the zinc oxide.

29: The method as set forth in claim 26, further comprising the steps of:
forming a photosensitive resist on the substrate so that the photosensitive resist is positioned on the side of the conductive layers;
patterning the photosensitive resist;
patterning the conductive layers by etching, with an etchant, the photosensitive resist having been patterned; and
peeling, with a peeling agent, the photosensitive resist from the substrate whose conductive layers have been patterned; wherein
the second conductive layer is made of material less likely to be eroded by the peeling agent than the zinc oxide.

30: The method as set forth in claim 29, wherein the conductive layers are etched with the same etchant and in the same step of patterning the conductive layers.
